(19) United States
(12) Patent Application Publication
(10) Pub. No.: US 2014/0252919 A1
(43) Pub. Date: Sep. 11, 2014

(54) PIEZOELECTRIC DEVICE

(71) Applicant: NIHON DEMPA KOGYO CO., LTD., Tokyo (JP)

(72) Inventors: TAKUMI ARIJI, SAITAMA (JP); TAKEHIRO TAKAHASHI, SAITAMA (JP); SHINICHI ASANO, MIYAGI (JP); TAICHI HAYASAKA, MIYAGI (JP); HIROMASA NAKATAKE, SAITAMA (JP); SHUICHI MIZUSAWA, SAITAMA (JP)

(73) Assignee: NIHON DEMPA KOGYO CO., LTD., Tokyo (JP)

(21) Appl. No.: 14/188,694

(22) Filed: Feb. 25, 2014

(30) Foreign Application Priority Data
Mar. 11, 2013 (JP) 2013-047714

(51) Int. Cl. H01L 41/047; H01L 41/053

(52) U.S. Cl. CPC H01L 41/0475; H01L 41/0533
USPC 310/344

(57) ABSTRACT

A piezoelectric device includes a piezoelectric vibrating piece, a lid portion, and a base portion. The piezoelectric vibrating piece includes a vibrating portion, a framing portion surrounding the vibrating portion, an excitation electrode on the vibrating portion, and an extraction electrode on the framing portion. The extraction electrode is electrically connected to the excitation electrode. The lid portion is bonded to a front surface of the piezoelectric vibrating piece. The base portion is bonded to a back surface of the piezoelectric vibrating piece. The base portion includes an external electrode electrically connected to the extraction electrodes. The framing portion includes a metallic layer that allows a passivation. The metallic layer is disposed at an outer peripheral edge portion corresponding to the extraction electrode on at least one of a front surface and a back surface.

### CROSS REFERENCE TO RELATED APPLICATIONS

This application claims the priority benefit of Japan application serial no. 2013-047714, filed on Mar. 11, 2013. The entirety of the above-mentioned patent application is hereby incorporated by reference herein and made a part of this specification.

### TECHNICAL FIELD

This disclosure relates to a piezoelectric device.

### DESCRIPTION OF THE RELATED ART

A known type of piezoelectric device includes a lid portion, which is bonded to a front surface (one principal surface) via a bonding material of a piezoelectric vibrating piece such as a quartz crystal piece, and a base portion, which is similarly bonded to a back surface (the other principal surface) of the piezoelectric vibrating piece via a bonding material. The piezoelectric vibrating piece used in this type includes a vibrating portion that vibrates at a predetermined vibration frequency, a framing portion formed to surround the vibrating portion, and a connecting portion that connects the vibrating portion and the framing portion together. At the front surface and the back surface of the vibrating portion of the piezoelectric vibrating piece, respective excitation electrodes are formed and respective extraction electrodes are formed from the respective excitation electrodes to the framing portion. These extraction electrodes electrically connect to respective external electrodes of the base portion.

For example, Japanese Unexamined Patent Application Publication No. 2010-200118 (hereinafter referred to as Patent Literature 1) discloses a piezoelectric device where a piezoelectric vibrating piece that includes respective extraction electrodes extracted from excitation electrodes to a framing portion is sandwiched between a lid portion and a base portion. The extraction electrodes included in this piezoelectric vibrating piece are formed to the outermost periphery of the framing portion. Even in a state where the lid portion and the base portion are bonded to the piezoelectric vibrating piece (that is, in a completed state as the piezoelectric device), side surfaces of the extraction electrodes are exposed to the exterior.

In the piezoelectric device disclosed in Patent Literature 1, the side surfaces of the extraction electrodes are exposed to the exterior. Accordingly, these side surfaces are exposed to the outside air. The metal used for the extraction electrode may be corroded (dissolved) by water vapor in the atmosphere. This corrosion reduces bonding strength of the lid portion and the base portion to the piezoelectric vibrating piece and may cause damage of the piezoelectric device such as peeling off of the lid portion and the base portion from the piezoelectric vibrating piece. Generally, the internal space (the space where the vibrating portion is held) of the piezoelectric device is formed under a predetermined atmosphere, for example, is vacuumed. However, the outside air may invade the internal space via a corroded extraction electrode. This may lead to reduction in reliability of the piezoelectric device such as variation in vibration frequency or cause of damage on the excitation electrode.

A need thus exists for a piezoelectric device which is not susceptible to the drawbacks mentioned above.

### SUMMARY

A piezoelectric device according to the disclosure includes a piezoelectric vibrating piece, a lid portion, and a base portion. The piezoelectric vibrating piece includes a vibrating portion, a framing portion surrounding the vibrating portion, an excitation electrode on the vibrating portion, and an extraction electrode on the framing portion. The extraction electrode is electrically connected to the excitation electrode. The lid portion is bonded to a front surface of the piezoelectric vibrating piece. The base portion is bonded to a back surface of the piezoelectric vibrating piece. The base portion includes an external electrode electrically connected to the extraction electrodes. The framing portion includes a metallic layer that allows a passivation. The metallic layer is disposed at an outer peripheral edge portion corresponding to the extraction electrode on at least one of the front surface and the back surface.

### BRIEF DESCRIPTION OF THE DRAWINGS

The foregoing and additional features and characteristics of this disclosure will become more apparent from the following detailed description considered with reference to the accompanying drawings.

FIG. 1A is a cross-sectional view illustrating a piezoelectric device according to a first embodiment.

FIG. 1B is a plan view illustrating a front surface of the piezoelectric vibrating piece viewed from its front surface side.

FIG. 1C is a plan view illustrating a back surface of the piezoelectric vibrating piece viewed from its front surface side.

FIG. 2 is an exploded perspective view illustrating a piezoelectric device according to the first embodiment.

FIG. 3A is a cross-sectional view illustrating a piezoelectric device according to a second embodiment.

FIG. 3B is a plan view illustrating a front surface of the piezoelectric vibrating piece viewed from its front surface side.

FIG. 3C is a plan view illustrating a back surface of the piezoelectric vibrating piece viewed from its front surface side.

FIG. 4A is a cross-sectional view illustrating a piezoelectric device according to a third embodiment.

FIG. 4B is a plan view illustrating a front surface of the piezoelectric vibrating piece viewed from its front surface side.

FIG. 4C is a plan view illustrating a back surface of the piezoelectric vibrating piece viewed from its front surface side.

FIG. 5A is a cross-sectional view illustrating a piezoelectric device according to a fourth embodiment.

FIG. 5B is a plan view illustrating a front surface of the piezoelectric vibrating piece viewed from its front surface side.

FIG. 5C is a plan view illustrating a back surface of the piezoelectric vibrating piece viewed from its front surface side.

FIG. 6A is a cross-sectional view illustrating a piezoelectric device according to a fifth embodiment.

FIG. 6B is a plan view illustrating a front surface of the piezoelectric vibrating piece viewed from its front surface side.

FIG. 6C is a plan view illustrating a back surface of the piezoelectric vibrating piece viewed from its front surface side.

FIG. 7A is a cross-sectional view illustrating a piezoelectric device according to the sixth embodiment.

FIG. 7B is a plan view illustrating a front surface of the piezoelectric vibrating piece viewed from its front surface side.

FIG. 7C is a plan view illustrating a back surface of the piezoelectric vibrating piece viewed from its front surface side.

### DETAILED DESCRIPTION

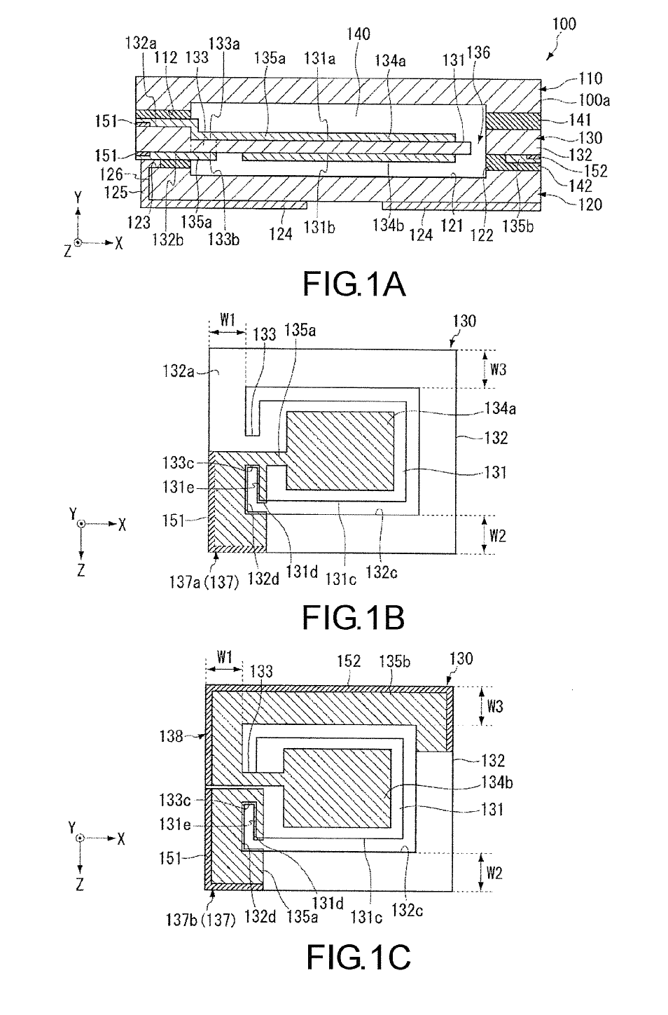

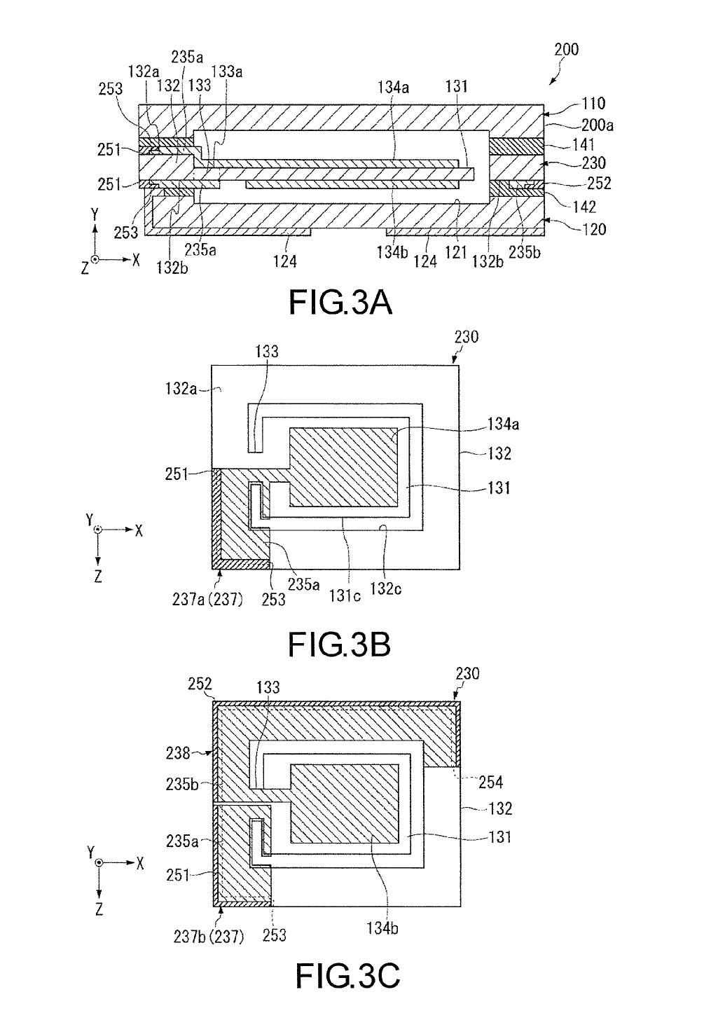

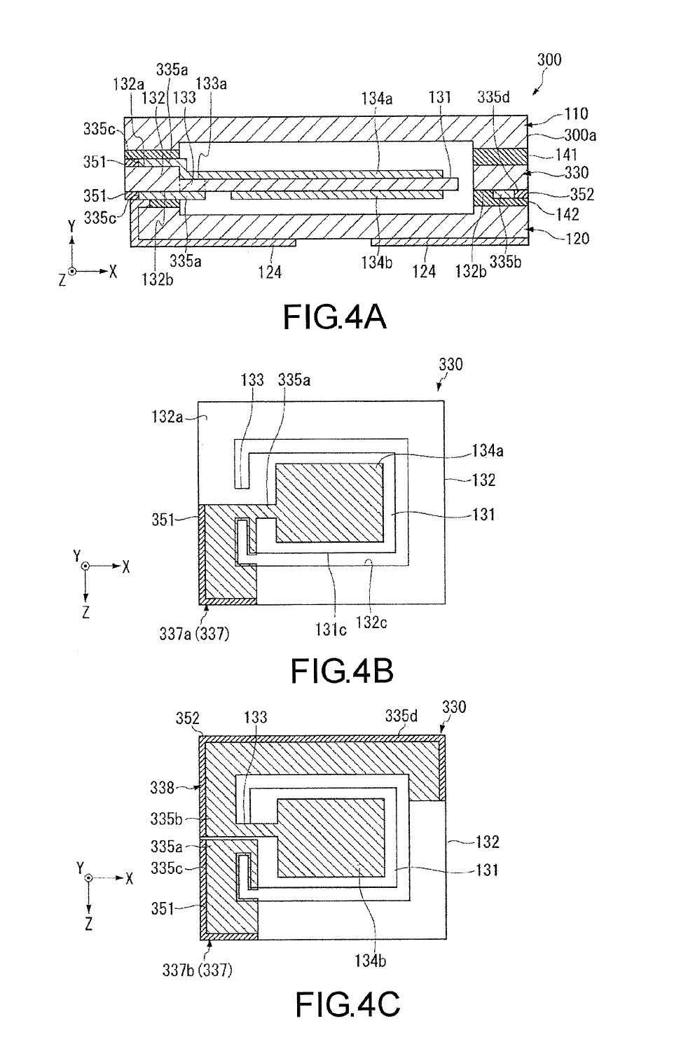

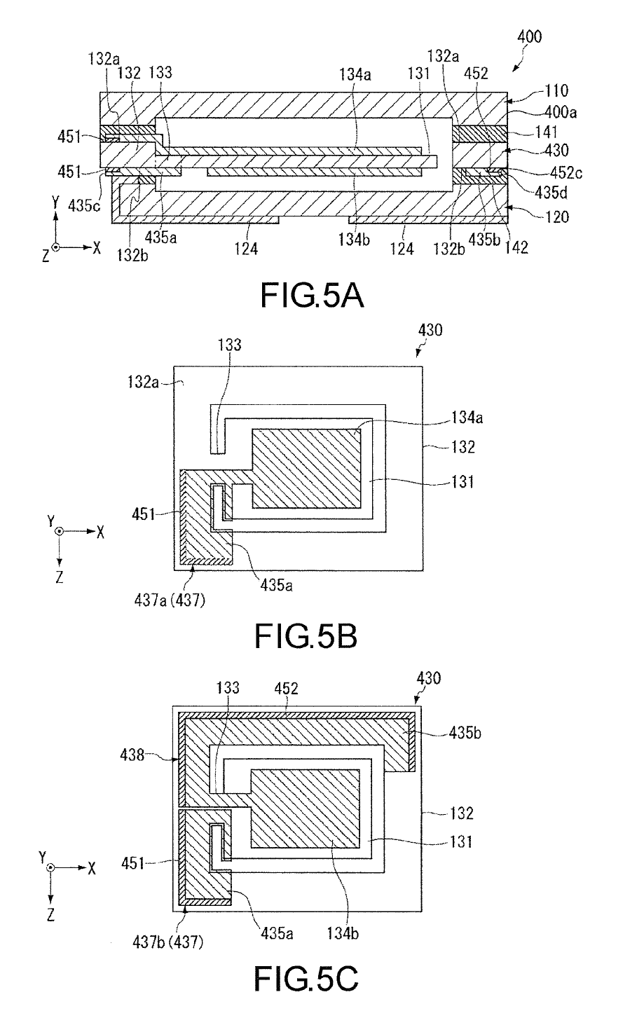

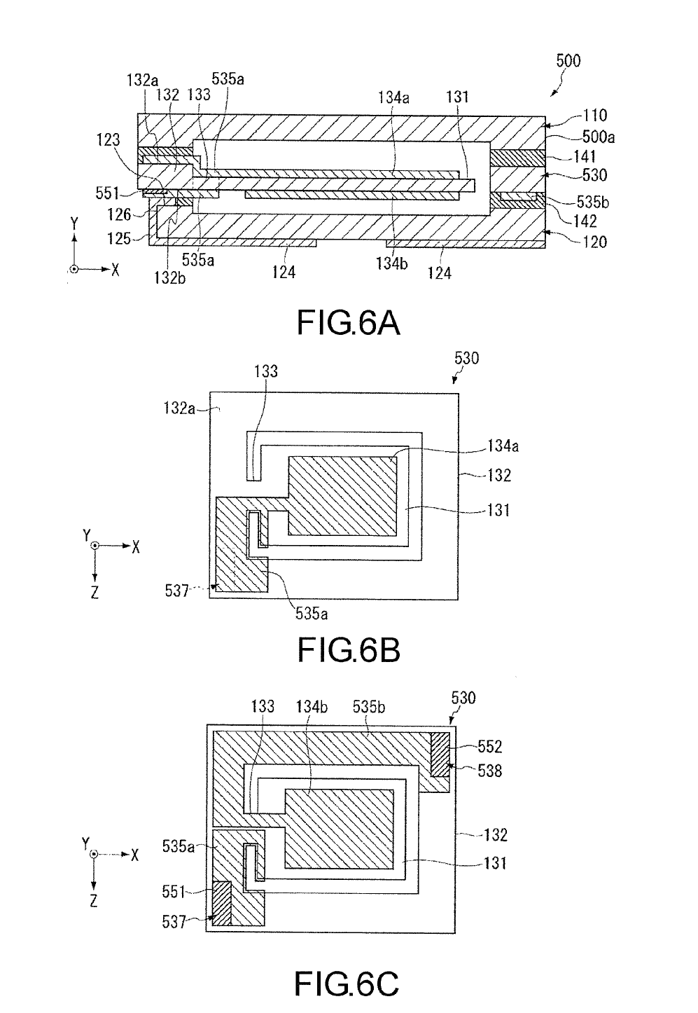

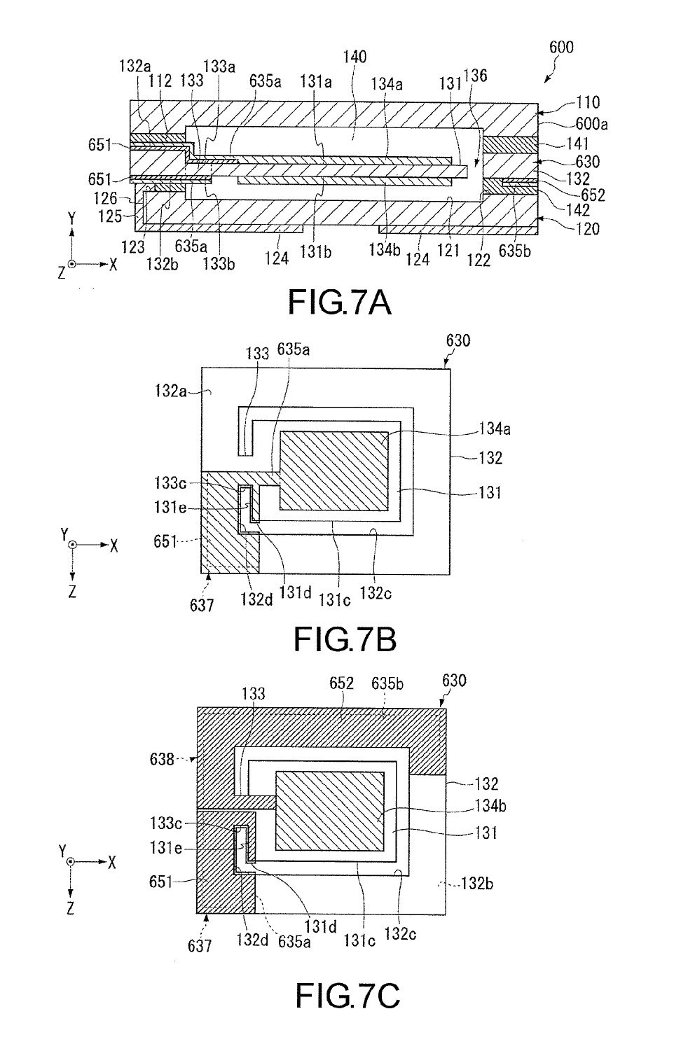

Hereinafter, a description will be given of a piezoelectric device according to embodiments disclosed here with reference to accompanying drawings. However, this disclosure is not limited to the following description. In the following embodiments, the drawings are expressed by changing the scale as necessary in order to describe the embodiments. For example, the illustration is partially enlarged to be emphasized. In the drawings excluding cross-sectional views such as FIG. 1A, FIG. 3A, FIG. 4A, FIG. 5A, FIG. 6A, and FIG. 7A, a hatched portion represents a conductive film.

### First Embodiment

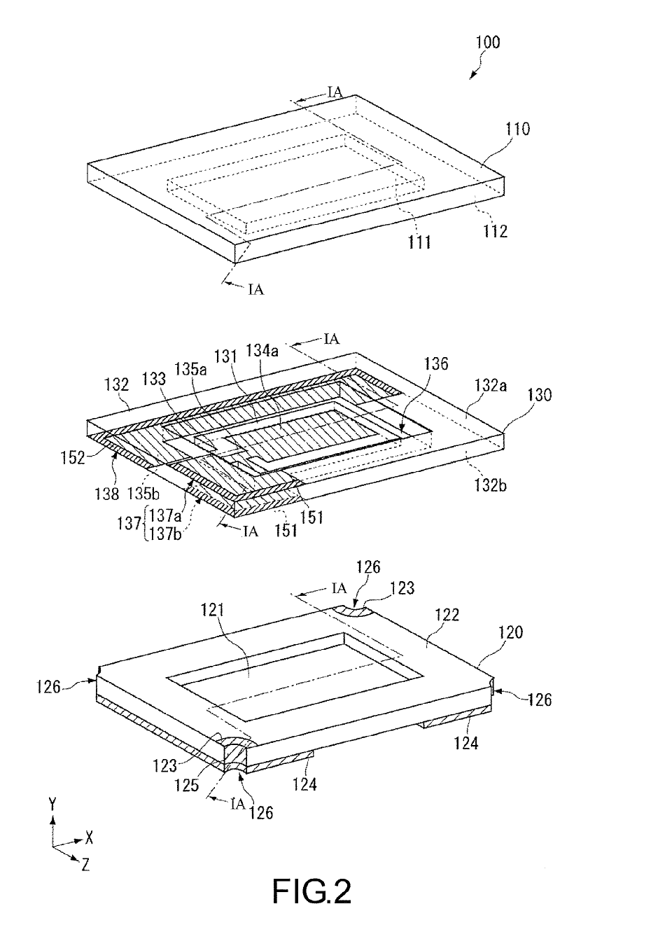

As illustrated in FIG. 1A and FIG. 2, a piezoelectric device 100 includes a lid portion 110, a base portion 120, and a piezoelectric vibrating piece 130. FIG. 1A illustrates a configuration taken along the line IA-IA of FIG. 2. The following description assumes that the long side direction of the piezoelectric device 100 is the X-axis direction, the height direction of the piezoelectric device 100 is the Y-axis direction, and the direction perpendicular to the X- and Y-axis direction is the Z-axis direction.

The piezoelectric vibrating piece 130, the lid portion 110, and the base portion 120 employ, for example, an AT-cut quartz-crystal material. AT-cut has, for example, an advantage that stable frequency characteristics are obtained in a wide temperature range. AT-cut is a processing method for cutting out the quartz crystal at an angle inclined at 35° 15′ around the crystallographic axis with respect to the optical axis among the electric axis, the mechanical axis, and the optical axis, which are three crystallographic axes of the synthetic quartz crystal.

The piezoelectric vibrating piece 130 includes a vibrating portion 131, a framing portion 132, and a connecting portion 133. The vibrating portion 131 vibrates at a predetermined vibration frequency. The framing portion 132 surrounds the vibrating portion 131. The connecting portion 133 connects the vibrating portion 131 and the framing portion 132. Excitation electrodes 134a and 134b are respectively formed on a front surface (a surface of a +Y side) 131a and a back surface (a surface of a −Y side) 131b of the vibrating portion 131. From the excitation electrodes 134a and 134b, extraction electrodes 135a and 135b are respectively formed on a front surface 132a and a back surface 132b of the framing portion 132 via a front surface (a surface of the +Y side) 133a and a back surface (a surface of the −Y side) 133b of the connecting portion 133. At a portion between the vibrating portion 131 and the framing portion 132 but excluding the connecting portion 133, a through hole 136 that passes through the piezoelectric vibrating piece 130 in the Y-axis direction is formed.

The base portion 120 is formed in a rectangular plate shape as illustrated in FIG. 1A and FIG. 2. The base portion 120 includes a depressed portion 121 formed on the front surface (the surface of the +Y side), a bonding surface 122 surrounding the depressed portion 121, and a connection electrode 123 disposed at two diagonal corner portions among four corner portions of the bonding surface 122. The bonding surface 122 is bonded to the back surface 132b of the framing portion 132 of the piezoelectric vibrating piece 130 via a bonding material 142.

On the back surface (the surface of the −Y side) of the base portion 120, external electrodes 124 are disposed respectively as a pair of mounting terminals. On side surfaces at four corner portions of the base portion 120, castellations (cutout portions) 126 are formed. The connection electrode 123 is disposed on two of the four castellations 126, and a castellation electrode 125 is formed on each of the two castellations. The castellation electrodes 125 electrically connect the connection electrode 123 and the external electrode 124. One of the two connection electrodes 123 is electrically connected to the extraction electrodes 135a of the piezoelectric vibrating piece 130. The other connection electrode 123 is electrically connected to the extraction electrodes 135b of the piezoelectric vibrating piece 130.

The lid portion 110 is formed in a rectangular plate shape as illustrated in FIG. 1A and FIG. 2. The lid portion 110 includes a depressed portion 111 formed on the back surface (the surface of the −Y side) and a bonding surface 112 that surrounds the depressed portion 111. The bonding surface 112 is bonded to the front surface 132a of the framing portion 132 of the piezoelectric vibrating piece 130 via the bonding material 141.

Thus, the piezoelectric device 100 includes the lid portion 110 disposed at the front surface side and the base portion 120 at the back surface side of the piezoelectric vibrating piece 130. Inside the piezoelectric device 100, the depressed portion 111 of the lid portion 110 and the depressed portion 121 of the base portion 120 forms a cavity 140. The vibrating portion 131 of the piezoelectric vibrating piece 130 is disposed in the cavity 140. The cavity 140 is sealed by the bonding material 141 disposed between the bonding surface 112 of the lid portion 110 and the front surface 132a of the framing portion 132, and the bonding material 142 disposed between the bonding surface 122 of the base portion 120 and the back surface 132b of the framing portion 132. The cavity 140 is set to, for example, a vacuum atmosphere or an inert gas atmosphere such as nitrogen and argon.

The extraction electrodes 135a and 135b formed at the framing portion 132 are electrically connected to the respective two connection electrodes 123 formed at the base portion 120 when the base portion 120 is bonded to the piezoelectric vibrating piece 130. Accordingly, each of the excitation electrodes 134a and 134b is electrically connected to each of the external electrodes 124 via the connection electrode 123 and the castellation electrode 125. The connection electrode 123 and the castellation electrode 125 serve as wiring for connecting the excitation electrodes 134a and 134b and the external electrode 124.

Electrodes formed in the piezoelectric vibrating piece 130 each have a two-layer structure having a first metallic layer formed on a front surface of a crystal element that constitutes the piezoelectric vibrating piece 130 and a second metallic layer formed on a front surface of this first metallic layer. The first metallic layer has a function to enhance adhesion of each electrode to the crystal element that constitutes the piezoelectric vibrating piece 130. The first metallic layer is formed of, for example, nickel tungsten (NiW). As a material for the first metallic layer, other than nickel tungsten, nickel may be employed alone as well as other kinds of alloy containing nickel (Ni) (for example, alloy of nickel and titanium (Ti) or alloy of nickel and copper (Cu)). Such first metallic layer is applicable to the second to sixth embodiments, which will be described later, as well as to the first embodiment. A second metallic layer has a function to protect electrodes while ensuring conductivity, and the second metallic layer is formed of, for example, gold (Au). Gold (Au) is chemically stable, therefore protecting each electrode from corrosion and similar trouble.

As illustrated in FIG. 1B, the extraction electrode 135a is formed in a rectangular region (in a bottom left region of FIG. 1B) near +Z and −X sides on the front surface of the piezoelectric vibrating piece 130 in a state of being electrically connected to the excitation electrode 134a. This region includes a part of the through hole 136. This extraction electrode 135a is extracted from the excitation electrode 134a in a belt-like shape and formed over a part of the front surface 131a of the vibrating portion 131, a part of the front surface 133a of the connecting portion 133, and a part of the front surface 132a of the framing portion 132.

Further, the extraction electrodes 135a are each formed in a partial region 131d of a +Z side end surface 131c of the vibrating portion 131, on a −X side end surface 131e of the vibrating portion 131, on a +Z side end surface 133c of the connecting portion 133, in the partial region 131d of an internal side surface 132c of the framing portion 132, and a facing region 132d, which faces the end surface 131e as well. Additionally, the extraction electrode 135a is formed in a partial region of the back surface 132b of the framing portion 132 (see FIG. 1C). The extraction electrodes 135a disposed on the front surface 132a and the back surface 132b of the framing portion 132 are electrically connected to each other via, for example, the partial region 131d. When viewed in the Y direction, a region disposed, for example, on the front surface 132a of the framing portion 132 and a region disposed on the back surface 132b of the extraction electrodes 135a overlap each other except the belt-like shape portion extending from the excitation electrode 134a. Additionally, these extraction electrodes 135a are not electrically connected to the excitation electrode 134b or the extraction electrodes 135b on the back surface of the piezoelectric vibrating piece 130.

On the other hand, the extraction electrode 135b is formed in a −Z side region (an upper region in FIG. 1C) on the back surface of the piezoelectric vibrating piece 130, in a state of being electrically connected to the excitation electrode 134b, as illustrated in FIG. 1C. The extraction electrode 135b is formed over a part of the back surface 131b of the vibrating portion 131, a part of the back surface 133b of the connecting portion 133, and a part of the back surface 132b of the framing portion 132.

Further, the extraction electrode 135b is formed in a belt-like shape in the −X direction from the −X sided side of the excitation electrode 134b, and then in the +X direction from the −Z direction along the framing portion 132, and formed to fold back in the +Z direction. The extraction electrode 135b is formed only on the back surface of the piezoelectric vibrating piece 130, not on the front surface of the piezoelectric vibrating piece 130. As described above, the extraction electrode 135b is not electrically connected to the excitation electrode 134a and the extraction electrodes 135a.

As illustrated in FIG. 1B and FIG. 1C, the extraction electrodes 135a and 135b are formed over the entirety of widths W1, W2, and W3 of the framing portion 132 respectively on the front surface 132a and the back surface 132b. The width W1 represents a length in the X direction at a −X side portion of the framing portions 132, the width W2 represents a length in the Z direction at a +Z side portion of the framing portions 132, and the width W3 represents a length in the Z direction at a −Z side portion. Employing such a wide region suppresses a rise in electric resistance caused by the extraction electrodes 135a and 135b and a rise in a crystal impedance value of the piezoelectric vibrating piece 130.

At the outer peripheral edge of the piezoelectric vibrating piece 130, as illustrated in FIG. 1A, metallic layers 151 and 152 are respectively formed between: the front surface 132a and the back surface 132b of the framing portion 132; and the extraction electrodes 135a and 135b by a metallic material that can be rendered passive, such as chrome (Cr). In addition to chrome (Cr), aluminum (Al), titanium (Ti), or alloy of these materials, for example, may be employed as a metallic material that constitutes the metallic layers 151 and 152.

The metallic layer 151 is formed at an outer peripheral edge portion 137 of the front surface 132a and the back surface 132b of the framing portion 132, which corresponds to the extraction electrode 135a. Advantages that the metallic layer 151 is formed at the outer peripheral edge portion 137 are as follows. Chrome used for the metallic layer 151 has a resistance value larger than, for example, gold, and additionally has a property of diffusing to nickel tungsten or gold. Accordingly, if, for example, chrome is formed on the whole bottom surface of the excitation electrode 134a or the extraction electrodes 135a and 135b, a total resistance value of the electrode will increase, resulting in an increase in a CI value. On the other hand, forming chrome only at the outer peripheral edge portion 137 reduces chrome consumption, thus avoiding a larger resistance value of the whole electrode and preventing the CI from deteriorating.

The outer peripheral edge portion 137 includes a front side region 137a and a back side region 137b. As illustrated in FIG. 1B, the front side region 137a includes a belt-like shaped region extending to a corner portion along the −X sided side in the +Z direction and a belt-like shaped region extending halfway from this corner portion along the +Z sided side in the +X direction of the front surface 132a. As illustrated in FIG. 1C, the back side region 137b includes a belt-like shaped region extending to a corner portion along the −X sided side in the +Z direction and a belt-like shaped region extending from the corner portion along the +Z sided side in the +X direction of the back surface 132b. Here, the front side region 137a and the back side region 137b are disposed to overlap when viewed from the Y perspective.

The metallic layer 152 is formed at an outer peripheral edge portion 138, to which the extraction electrode 135b corresponds, in the back surface 132b of the framing portion 132. The outer peripheral edge portion 138 includes a belt-like shaped region extending to a corner portion along the −X sided side in the −Z direction, a belt-like shaped region extending from this corner portion to another corner portion along the −Z sided side in the +X direction, and a belt-like shaped region extending halfway from this corner portion along the +X sided end side in the +Z direction of the back surface 132b. Since the metallic layers 151 and 152 are thus disposed at the outer peripheral edge portions 137 and 138 of the framing portion 132, end surfaces of the metallic layers 151 and 152 are exposed to an outer side surface 100a of the piezoelectric device 100, together with the extraction electrodes 135a and 135b, as illustrated, for example, in FIG. 1A.

Since the metallic layers 151 and 152 and the extraction electrodes 135a and 135b are laminated at the outer peripheral edge portions 137 and 138, some of metal atoms constituting the metallic layers 151 and 152 (for example, chrome atoms) diffuse into the extraction electrodes 135a and 135b over time (diffuse into NiW of a first metallic layer, in particular). The some of the metal atoms that have diffused into the extraction electrodes 135a and 135b then reach the side surface 100a of the piezoelectric device 100 to form an oxidized film in contact with the outside air. This puts outer end surfaces of the extraction electrodes 135a and 135b into a state where a corrosion-resistant oxidized film is formed, that is, a state where a passivation has been made. The end surfaces of the extraction electrodes 135a and 135b (the end surfaces of the first metallic layer of NiW and others, in particular) will be covered by the passivation to insulate the outside air.

As described above, according to the first embodiment, the metallic layers 151 and 152 formed at the outer peripheral edge portion 137 and 138 of the extraction electrodes 135a and 135b forms passivation on the end surfaces of the extraction electrodes 135a and 135b. This suppresses corrosion and similar problems at the extraction electrodes 135a and 135b (particularly at the first metallic layer such as NiW). This prevents damages of the piezoelectric device 100, such as a poor bonding of the lid portion 110 or the base portion 120, and also maintains the sealing of bonding portions to hold an atmosphere of the cavity 140, thus ensuring operation reliability of the piezoelectric device 100.

Next, a description will be given of a fabrication method of the piezoelectric device 100 constituted as described above. In a fabrication process of the piezoelectric vibrating pieces 130, multiple piezoelectric vibrating pieces 130 are taken by cutting out the individual piezoelectric vibrating pieces 130 from a wafer fabricated, for example, by AT-cut of the synthetic quartz crystal. At the time of cutting out the pieces, a thickness of the wafer is adjusted such that the vibrating portion 131 constituting the piezoelectric vibrating piece 130 has a desired frequency characteristic. This thickness adjustment can be performed, for example, by etching the region including the vibrating portion 131 in the wafer. Subsequently, vibrating portions 131, framing portions 132, and the connecting portions 133 are formed on the wafer by photolithography and etching.

Subsequently, excitation electrodes 134a and 134b, extraction electrodes 135a and 135b, and metallic layers 151 and 152 are formed at the vibrating portion 131, the framing portion 132, and the connecting portion 133. First, a chrome (Cr) layer is formed on the front surface 132a and the back surface 132b of the framing portion 132 to form a resist pattern so that the metallic layers 151 and 152 will be formed by photolithography. Then, a conductive film, for example, is formed at the vibrating portion 131, the framing portion 132, and the connecting portion 133, and a resist pattern of the conductive film is subsequently formed so that a conductive film will be formed on each of the front and back surface sides by photolithography. This conductive film has a two-layer structure where a first metallic layer, which is formed of nickel tungsten (NiW), is disposed on a lower-layer side and a second metallic layer, which is formed of gold (Au), is disposed on an upper-layer side. This conductive film is formed from the front and back surface sides of the wafer by, for example, evaporation or sputtering. Here, since a groove or slit is preliminarily formed on the wafer, a conductive film is formed, for example, on the side surface of the connecting portion 133.

In parallel with manufacturing the piezoelectric vibrating piece 130, the lid portion 110 and the base portion 120 are also manufactured. Similarly to the piezoelectric vibrating piece 130, the multiple lid portions 110 and the multiple base portions 120 are also taken by cutting out individual portions from a wafer. In the lid portion 110, the depressed portion 111 is formed on the back surface of the wafer by photolithography and etching. In the base portion 120, the depressed portion 121 and a castellation (a cutout portion) 126 are formed on the front surface of the wafer by photolithography and etching, and the connection electrode 123, the external electrode 124, and the castellation electrode 125 are respectively formed at predetermined portions.

Subsequently, under vacuum atmosphere, the wafer where the lid portions 110 are formed is bonded to the front surface of the wafer where the piezoelectric vibrating pieces 130 are formed via a bonding material 141, while the wafer where the base portions 120 are formed is bonded to the back surface of the wafer where the piezoelectric vibrating pieces 130 are formed via the bonding material 142. Subsequently, the bonded wafers are cut along preliminarily designed scribe lines to complete individual piezoelectric devices 100. Here, the fabrication method of the piezoelectric device 100 is not limited to the above-described method, and various methods are employed.

### Second Embodiment

Next, a description will be given of a piezoelectric device 200 according to a second embodiment. Like reference numerals designate corresponding or identical elements to those of the first embodiment, and therefore such elements will not be further elaborated here.

As illustrated in FIGS. 3A to 3C, in the piezoelectric device 200, extraction electrodes 235a and 235b, which are formed at a piezoelectric vibrating piece 230, are not formed up to an outer peripheral edge of the framing portion 132. Outer peripheral edges of these extraction electrodes 235a and 235b are both formed away from the outer peripheral edge of the framing portion 132 in the front surface 132a and the back surface 132b. Metallic layers 251 and 252 are formed at outer peripheral edge portions 237 and 238 of the front surface 132a and the back surface 132b of the framing portion 132. Outer peripheral edges of the metallic layers 251 and 252 are formed up to the outer peripheral edge of the framing portion 132. Inner portions 253 and 254 of the metallic layers 251 and 252 are formed covering the outer peripheral edges of the extraction electrodes 235a and 235b. Here, the extraction electrodes 235a and 235b are similar to the extraction electrodes 135a and 135b, which are shown in the first embodiment, except the shape near the outer peripheral edge of the framing portion 132.

Here, the outer peripheral edge portion 237 includes a front side region 237a and a back side region 237b, similarly to the first embodiment. The metallic layer 251 is formed in each of the front side region 237a and the back side region 237b of the outer peripheral edge portion 237. Additionally, the inner portions 253 and 254 of the metallic layers 251 and 252 are laminated with the extraction electrodes 235a and 235b. Here, the metallic layers 251 and 252 are formed of a metallic material similar to that of the metallic layers 151 and 152 in the first embodiment. Additionally, the metallic layers 251 and 252 are exposed on a side surface 200a of the piezoelectric device 200. The exposed surface is oxidized by water vapor in the atmosphere to form a passivation film.

According to the second embodiment, the outer peripheral edges of the extraction electrodes 235a and 235b are disposed away from the outer peripheral edge of the framing portion 132 and covered with the metallic layers 251 and 252. This suppresses corrosion of the extraction electrodes 235a and 235b and similar problems. Additionally, on the exposed surfaces of the metallic layers 251 and 252, a passivation film is formed to further reduce an effect of the outside air, thus suppressing corrosion of the extraction electrodes 235a and 235b and similar problems. Similarly to the first embodiment, the second embodiment can prevent poor bonding of the lid portion 110 and others, and also maintain the sealing at the bonding portions.

The fabrication method of the piezoelectric device 200 is almost similar to that in the first embodiment, except the formation of the extraction electrodes 235a and 235b and the metallic layers 251 and 252. Similarly to the first embodiment, the vibrating portion 131, the framing portion 132, and the connecting portion 133 are formed first for fabricating the piezoelectric vibrating piece 230. Next, a resist pattern is formed for the extraction electrodes 235a and 235b along with the excitation electrodes 134a and 134b, and then, the metallic layers 251 and 252 are formed at the outer peripheral edge portions 237 and 238. Similarly to the first embodiment, the lid portion 110 and the base portion 120 are subsequently bonded to the piezoelectric vibrating piece 230 via the bonding materials 141 and 142, and the bonded wafers are cut along the scribe lines.

### Third Embodiment

Next, a description will be given of a piezoelectric device 300 according to a third embodiment. Like reference numerals designate corresponding or identical elements to those of the first embodiment, and therefore such elements will not be further elaborated here.

As illustrated in FIGS. 4A to 4C, in the piezoelectric device 300, outer peripheral edges of extraction electrodes 335a and 335b formed at a piezoelectric vibrating piece 330 are formed away from the outer peripheral edge of the framing portion 132, similarly to the second embodiment. Metallic layers 351 and 352 are formed at outer peripheral edge portions 337 and 338 of the front surface 132a and the back surface 132b of the framing portion 132. Outer peripheral edges of the metallic layers 351 and 352 are formed up to the outer peripheral edge of the framing portion 132. Inner end surfaces of the metallic layers 351 and 352 are formed in contact with outer end surfaces 335c and 335d of the extraction electrodes 335a and 335b. However, the inner end surfaces of the metallic layer 351 and 352 and the outer end surfaces 335c and 335d of the extraction electrodes 335a and 335b do not have to contact each other and may be away from each other. Here, the extraction electrodes 335a and 335b are similar to the extraction electrodes 135a and 135b, which are shown in the first embodiment, except the shape near the outer peripheral edge of the framing portion 132.

Here, the outer peripheral edge portion 337 includes a front side region 337a and a back side region 337b, similarly to the first embodiment. The metallic layer 351 is formed in both of the front side region 337a and the back side region 337b of the outer peripheral edge portion 337. Additionally, the metallic layers 351 and 352 are formed of a metallic material similar to that of the metallic layers 151 and 152 in the first embodiment. Additionally, the extraction electrodes 335a and 335b are formed to have a film thickness identical to that of the metallic layers 351 and 352, but may have a different thickness. The metallic layers 351 and 352 are exposed on a side surface 300a of the piezoelectric device 300. The exposed surface is oxidized by water vapor in the atmosphere to form a passivation film.

According to the third embodiment, the outer peripheral edges of the extraction electrodes 335a and 335b are disposed away from the outer peripheral edge of the framing portion 132, and the metallic layers 351 and 352 are formed in the spaced portion. This suppresses corrosion of the extraction electrodes 335a and 335b and similar problems. Additionally, on the exposed surface of the metallic layers 351 and 352, a passivation film is formed to further reduce an effect of the outside air. This can suppress corrosion of the extraction electrodes 335a and 335b and similar problems. Similarly to the first embodiment, this can prevent poor bonding of the lid portion 110 and others, and also maintain the sealing at the bonding portions.

The fabrication method of the piezoelectric device 300 is almost similar to that of the first embodiment, except the formation of the extraction electrodes 335a and 335b and the metallic layers 351 and 352. Similarly to the first embodiment, the vibrating portion 131, the framing portion 132, and the connecting portion 133 are formed first for fabricating the piezoelectric vibrating piece 330. Next, ones of the extraction electrodes 335a and 335b (including the excitation electrodes 134a and 134b) and the metallic layers 351 and 352 are formed before the others are formed. There is no particular forming order. Similarly to the first embodiment, the lid portion 110 and the base portion 120 are bonded to the piezoelectric vibrating piece 330 via the bonding material 141 and 142, and the bonded wafers are cut along the scribe lines.

### Fourth Embodiment

Next, a description will be given of a piezoelectric device 400 according to a fourth embodiment. Like reference numerals designate corresponding or identical elements to those of the above embodiments, and therefore such elements will not be further elaborated here.

As illustrated in FIGS. 5A to 5C, in the piezoelectric device 400, outer peripheral edges of extraction electrodes 435a and 435b formed at a piezoelectric vibrating piece 430 are formed away from the outer peripheral edge of the framing portion 132, similarly to the second embodiment. Metallic layers 451 and 452 are formed at outer peripheral edge portions 437 and 438, which are away from the outer peripheral edge of the framing portion 132 and in parallel with the outer peripheral edge of the framing portion 132, on the front surface 132a and the back surface 132b of the framing portion 132. The metallic layers 451 and 452 are not formed up to the outer peripheral edge of the framing portion 132, but are sandwiched between the framing portion 132 and the extraction electrodes 435a and 435b. In other words, at the outer peripheral edge portions 437 and 438, the extraction electrodes 435a and 435b and the metallic layers 451 and 452 are laminated with each other. Here, the metallic layer 451 and the metallic layer 452 overlap when viewed from the Y perspective. Additionally, the extraction electrodes 435a and 435b are similar to the extraction electrodes 135a and 135b, which are shown in the first embodiment, except the shape near the outer peripheral edge of the framing portion 132.

Here, the outer peripheral edge portion 437 includes a front side region 437a and a back surface region 437b similarly to the first embodiment. The metallic layer 451 is formed in both of the front side region 437a and the back surface region 437b of the outer peripheral edge portion 437. Additionally, the metallic layers 451 and 452 are formed of a metallic material similar to that of the metallic layers 151 and 152 in the first embodiment. The outer peripheral edges of the metallic layers 451 and 452 are covered with the bonding materials 141 and 142, and are not exposed at a side surface 400a of the piezoelectric device 400. Here, the extraction electrodes 435a and 435b are exposed at the castellation 126 (see FIG. 5A). However, as described in the first embodiment, metal atoms that constitute the metallic layers 451 and 452 diffuse into the extraction electrodes 435a and 435b, so as to form passivation on the exposed surfaces of the extraction electrodes 435a and 435b.

According to the fourth embodiment, the outer peripheral edges of the extraction electrodes 435a and 435b are disposed away from the outer peripheral edge of the framing portion 132 and covered with the bonding materials 141 and 142. This suppresses corrosion of the extraction electrodes 435a and 435b and similar problems. Additionally, even if the sealing achieved by the bonding materials 141 and 142 is lost, the metallic layers 451 and 452 (or metal atoms that constitute the metallic layers 451 and 452 that diffuse up to the front surfaces of the extraction electrodes 435a and 435b) come into contact with the outside air and oxidize to form a passivation film. This can suppress corrosion of the extraction electrodes 435a and 435b and similar problems. Similarly to the first embodiment, this can prevent poor bonding of the lid portion 110 and others, and also maintain the sealing at the bonding portions.

The fabrication method of the piezoelectric device 400 is almost similar to that in the first embodiment, except the formation of the extraction electrodes 435a and 435b and metallic layers 451 and 452. Also similarly to the first embodiment, the lid portion 110 and the base portion 120 are bonded to the piezoelectric vibrating piece 430 via the bonding material 141 and 142, and the bonded wafers are cut along the scribe lines. Here, in the fourth embodiment, the extraction electrodes 435a and 435b and the metallic layers 451 and 452 are laminated with each other at a location away from the outer peripheral edge of the framing portion 132. Alternatively, at a similar location, the outer peripheral edges of the extraction electrodes may be covered with the metallic layers as illustrated in the second embodiment, or in contact with the metallic layers as illustrated in the third embodiment.

### Fifth Embodiment

Next, a description will be given of a piezoelectric device 500 according to a fifth embodiment. Like reference numerals designate corresponding or identical elements to those of the above embodiments, and therefore such elements will not be further elaborated here.

As illustrated in FIGS. 6A to 6C, in the piezoelectric device 500, outer peripheral edges of extraction electrodes 535a and 535b formed at a piezoelectric vibrating piece 530 are formed away from the outer peripheral edge of the framing portion 132, similarly to the second embodiment. Metallic layers 551 and 552 are formed in rectangular regions (outer peripheral edge portions) 537 and 538, which are away from the outer peripheral edge of the framing portion 132 and corresponding to the castellation 126, on the back surface 132b of the framing portion 132. Here, the metallic layers 551 and 552 are not formed up to the outer peripheral edge of the framing portion 132, but are sandwiched between the framing portion 132 and the extraction electrodes 535a and 535b. In other words, in the regions 537 and 538, the extraction electrodes 535a and 535b and the metallic layers 551 and 552 are laminated with each other. Here, the metallic layer 551 is not formed on the front surface 132a of the framing portion 132. Additionally, the extraction electrodes 535a and 535b are similar to the extraction electrodes 135a and 135b, which are shown in the first embodiment, except the shape near the outer peripheral edge of the framing portion 132.

Additionally, the metallic layers 551 and 552 are formed of a metallic material similar to that of the metallic layers 151 and 152 in the first embodiment. The outer peripheral edges of the extraction electrodes 535a and 535b and the metallic layer 551 and 552 are covered with the bonding materials 141 and 142 except the castellation 126, and are not exposed at a side surface 500a of the piezoelectric device 500. The extraction electrodes 535a and 535b are exposed at the castellation 126 (see FIG. 6A). As described in the first embodiment, metal atoms that constitute the metallic layers 551 and 552 diffuse into the extraction electrodes 535a and 535b, so as to form passivation on the exposed surfaces of the extraction electrodes 535a and 535b.

According to the fifth embodiment, the outer peripheral edges of the extraction electrodes 535a and 535b are disposed away from the outer peripheral edge of the framing portion 132 and covered with the bonding materials 141 and 142. This suppresses corrosion of the extraction electrodes 535a and 535b and similar problems. Additionally, at the castellation 126, a passivation film is formed on the front surfaces of the extraction electrodes 535a and 535b. This can suppress the corrosion of the extraction electrodes 435a and 435b and similar problems. Similarly to the first embodiment, this can prevent poor bonding of the lid portion 110 and others, and also maintain the sealing at the bonding portions. Here, the regions 537 and 538 where the metallic layers 551 and 552 are formed are smaller than those in the other embodiments, thus resulting in smaller amount of metal required for the metallic layers 551 and 552. Additionally, the regions 537 and 538 have a simple shape such as a rectangular shape. It is therefore easy to form resist patterns, and this leads to easy manufacturing.

The fabrication method of the piezoelectric device 500 is almost similar to that in the first embodiment, except the formation of the extraction electrodes 535a and 535b and metallic layers 551 and 552. Similarly to the first embodiment, the vibrating portion 131, the framing portion 132, and the connecting portion 133 are formed first for fabricating the piezoelectric vibrating piece 530. Next, the metallic layers 551 and 552 are formed in the regions 537 and 538. Then the extraction electrodes 535a and 535b are formed, along with the excitation electrodes 134a and 134b. Similarly to the first embodiment, the lid portion 110 and the base portion 120 are bonded to the piezoelectric vibrating piece 530 via the bonding material 141 and 142, and the bonded wafers are cut along the scribe lines. Here, in the fifth embodiment, the extraction electrodes 535a and 535b and the metallic layers 551 and 552 are laminated with each other at a location away from the outer peripheral edge of the framing portion 132. Alternatively, the outer peripheral edges of the extraction electrodes may be covered with the metallic layers at a similar location as illustrated in the second embodiment.

### Sixth Embodiment

Next, a description will be given of a piezoelectric device 600 according to a sixth embodiment. Like reference numerals designate corresponding or identical elements to those of the first embodiment, and therefore such elements will not be further elaborated here.

As illustrated in FIGS. 7A to 7C, in the piezoelectric device 600, extraction electrodes 635a and 635b formed at a piezoelectric vibrating piece 630 are both formed up to their outer peripheral edges on the front surface 132a and the back surface 132b of the framing portion 132, similarly to the piezoelectric vibrating piece 130 in the first embodiment. Shapes of the extraction electrodes 635a and 635b are similar to those of the extraction electrodes 135a and 135b illustrated in the first embodiment.

Metallic layers 651 and 652 are formed in the same regions as those of the extraction electrodes 635a and 635b, except the excitation electrode 134a and 134b. In other words, the metallic layers 651 and 652 are, as illustrated in FIGS. 7B and 7C, formed on a part of the front surface 131a and the back surface 131b of the vibrating portion 131, on the front surface 133a and the back surface 133b of the connecting portion 133, and on the front surface 132a and the back surface 132b of the framing portion 132, and respectively laminated with the extraction electrodes 635a and 635b. Therefore, the metallic layers 651 and 652 serves as a foundation film for the extraction electrodes 635a and 635b. Here, these metallic layers 651 and 652 are formed to include outer peripheral edge portions 637 and 638 of the framing portion 132.

Additionally, an extraction electrode 635a is, similarly to the first embodiment, formed in the partial region 131d of the end surface 131c of the vibrating portion 131, the end surface 131e, the end surface 133c of the connecting portion 133, the facing region 132d of the internal side surface 132c of the framing portion 132 as well. The metallic layer 651 is formed as a foundation film in the partial region 131d, the end surface 131e, the end surface 133c, and the facing region 132d as well. Here, the metallic layers 651 and 652 are formed of a metallic material similar to that of the metallic layers 151 and 152 in the first embodiment.

Since the metallic layers 651 and 652 and the extraction electrodes 635a and 635b are laminated with each other, metal atoms that constitute the metallic layers 651 and 652 diffuse into the extraction electrodes 635a and 635b. The some of the metal atoms that have diffused into the extraction electrodes 635a and 635b then reach a side surface 600a of the piezoelectric device 600 to form an oxidized film in contact with the outside air and caused by water vapor in the atmosphere. This puts outer end surfaces of the extraction electrodes 635a and 635b into a state where a corrosion-resistant oxidized film or a state that has been rendered passive is formed, and the extraction electrodes 635a and 635b will be protected from the outside air by the passivation film.

According to the sixth embodiment, the outer peripheral edges of the extraction electrodes 635a and 635b are covered with the passivation film, similarly to the first embodiment. This suppresses corrosion of the extraction electrodes 635a and 635b and similar problems. Additionally, the metallic layers 651 and 652 are widely formed as foundation films for the extraction electrodes 635a and 635b. This allows the metallic layers 651 and 652 to sufficiently diffuse to the extraction electrodes 635a and 635b to ensure a formed passivation film. Since the metallic layer 651 and 652 are not formed at the excitation electrode 134a and 134b, this further reduces an influence on a vibration characteristic of the vibrating portion 131.

The fabrication method of the piezoelectric device 600 is almost similar to that in the first embodiment, except the formation of the extraction electrodes 635a and 635b and metallic layers 651 and 652. Similarly to the first embodiment, the vibrating portion 131, the framing portion 132, and the connecting portion 133 are formed first for fabricating the piezoelectric vibrating piece 630. Then, the metallic layers 651 and 652 are formed in the region where the extraction electrodes 635a and 635b are to be formed. Then, the excitation electrode 134a and 134b and the extraction electrodes 635a and 635b are formed. The extraction electrodes 635a and 635b are formed with the metallic layers 651 and 652 laminated. Here, the metallic layers 651 and 652 may not be formed before the excitation electrodes 134a and 134b and the extraction electrodes 635a and 635b are formed. For example, the excitation electrode 134a and 134b may be formed first, the metallic layer 651 and 652 may be then formed, and then the extraction electrodes 635a and 635b may be formed so that the extraction electrodes 635a and 635b will be laminated on the metallic layers 651 and 652. In this case, the metallic layers 651 and 652 and the extraction electrodes 635a and 635b are formed in the same region, and therefore formed by sputtering or evaporation using an identical metal mask. Similarly to the first embodiment, the lid portion 110 and the base portion 120 are bonded to the piezoelectric vibrating piece 630 via the bonding material 141 and 142, and the bonded wafers are cut along the scribe lines.

The first to sixth embodiments have been described above. However, this disclosure is not limited to the above-described embodiment, and various changes of the embodiment may be made without departing from the spirit and scope of the disclosure. The matters described in the first to sixth embodiments may be combined as necessary. For example, the first embodiment can be applied to the front surface of the piezoelectric vibrating piece while the second embodiment can be applied to the back surface. In the first to sixth embodiments, the bonding materials 141 and 142 are employed to bond the piezoelectric vibrating pieces 130, 230, 330, 430, 530, and 630 and the lid portion 110 or the base portion 120. This, however, should not be construed in a limiting sense. For example, the piezoelectric vibrating piece 130 or similar piece and the lid portion 110 or the piezoelectric vibrating piece 130 or similar piece and the base portion 120 may be directly bonded such as by glass bonding without using the bonding material 141 and 142.

While in the above-described embodiment the crystal unit (a piezoelectric resonator) is described as the piezoelectric device, an oscillator is also possible. In the case of the oscillator, an IC or similar member is mounted on the base portion 120, and the extraction electrodes 135a and similar member in the piezoelectric vibrating piece 130 and the external electrode 124 of the base portion 120 are connected to the IC. Additionally, the above-described embodiment employs the quartz crystal piece as the piezoelectric vibrating piece 130. Alternatively, a piezoelectric vibrating piece formed of lithium tantalite, lithium niobate, and similar material may be used. Additionally, the quartz-crystal material is used as the lid portion 110 and the base portion 120. Alternatively, glass, ceramic, or similar material may be used.

The metallic layer may also be disposed in a laminated state between the framing portion and the extraction electrode. Additionally, the extraction electrode may be formed away from an outer peripheral edge of the framing portion. The metallic layer may be formed with an end of the extraction electrode covered. Additionally, the extraction electrode may be formed away from an outer peripheral edge of the framing portion. The metallic layer may be disposed between the outer peripheral edge of the framing portion and the end of the extraction electrode. Additionally, the extraction electrode may be formed away from the outer peripheral edge of the framing portion. At four corners of the base portion, a cutout for allowing wiring from an external electrode to the extraction electrode may be formed. The metallic layer may be formed corresponding to an extraction electrode exposed by the cutout. Additionally, the metallic layer may be disposed corresponding to the extraction electrode that includes the outer peripheral edge portion and excludes the excitation electrode.

According to this embodiment, the metallic layer forms a passivation at the outer peripheral edge portion of the extraction electrode. This passivation film protects the extraction electrodes from water vapor in the atmosphere, thereby suppressing corrosion of the extraction electrodes and similar troubles. This prevents damages of the piezoelectric device, such as a poor bonding of lid portions, and also maintains the sealing of bonding portions to hold an atmosphere of the internal space, thus ensuring operation reliability.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A piezoelectric device, comprising:
a piezoelectric vibrating piece that includes a vibrating portion, a framing portion surrounding the vibrating portion, an excitation electrode on the vibrating portion, and an extraction electrode on the framing portion, the extraction electrode being electrically connected to the excitation electrode;
a lid portion, being bonded to a front surface of the piezoelectric vibrating piece;
a base portion, being bonded to a back surface of the piezoelectric vibrating piece, the base portion including an external electrode electrically connected to the extraction electrodes, wherein
the framing portion includes a metallic layer that allows a passivation, the metallic layer being disposed at an outer peripheral edge portion corresponding to the extraction electrode on at least one of the front surface and the back surface.

2. The piezoelectric device according to claim 1, wherein
the metallic layer is made of a material selected from a group consisting of chrome, aluminum, titanium, chromium alloy, aluminum alloy, and titanium alloy.

3. The piezoelectric device according to claim 1, wherein
the metallic layer is laminated between the framing portion and the extraction electrode.

4. The piezoelectric device according to claim 2, wherein
the metallic layer is laminated between the framing portion and the extraction electrode.

5. The piezoelectric device according to claim 1, wherein
the extraction electrode is diposed away from an outer peripheral edge of the framing portion, and
the metallic layer covers an end of the extraction electrode.

6. The piezoelectric device according to claim 2, wherein
the extraction electrode is diposed away from an outer peripheral edge of the framing portion, and
the metallic layer covers an end of the extraction electrode.

7. The piezoelectric device according to claim 1, wherein
the extraction electrode is diposed away from an outer peripheral edge of the framing portion, and
the metallic layer is disposed between an outer peripheral edge of the framing portion and an end of the extraction electrode.

8. The piezoelectric device according to claim 2, wherein
the extraction electrode is diposed away from an outer peripheral edge of the framing portion, and
the metallic layer is disposed between an outer peripheral edge of the framing portion and an end of the extraction electrode.

9. The piezoelectric device according to claim 7, wherein
the metallic layer has an end in contact with the end of the extraction electrode.

10. The piezoelectric device according to claim 8, wherein
the metallic layer has an end in contact with the end of the extraction electrode.

11. The piezoelectric device according to claim 7, wherein
the metallic layer has a same thickness as a thickness of the extraction electrode.

12. The piezoelectric device according to claim 8, wherein
the metallic layer has a same thickness as a thickness of the extraction electrode.

13. The piezoelectric device according to claim 9, wherein
the metallic layer has a same thickness as a thickness of the extraction electrode.

14. The piezoelectric device according to claim 10, wherein
the metallic layer has a same thickness as a thickness of the extraction electrode.

15. The piezoelectric device according to claim 1, wherein
the extraction electrode is diposed away from an outer peripheral edge of the framing portion, and
the base portion has cutout portions at four corners for wiring connecting the external electrode and the extraction electrodes,
the metallic layer is disposed corresponding to the extraction electrode exposed by the cutout portions.

16. The piezoelectric device according to claim 2, wherein
the extraction electrode is diposed away from an outer peripheral edge of the framing portion, and
the base portion has cutout portions at four corners for wiring connecting the external electrode and the extraction electrodes,
the metallic layer is disposed corresponding to the extraction electrode exposed by the cutout portions.

17. The piezoelectric device according to claim 1, wherein
the metallic layer is disposed corresponding to the extraction electrode that includes the outer peripheral edge portion and excludes the excitation electrode.

18. The piezoelectric device according to claim 2, wherein
the metallic layer is disposed corresponding to the extraction electrode that includes the outer peripheral edge portion and excludes the excitation electrode.
